(19) United States
(12) Patent Application Publication
(10) Pub. No.: US 2011/0147783 A1
(43) Pub. Date: Jun. 23, 2011

(54) RED PHOSPHOR AND FORMING METHOD THEREOF FOR USE IN SOLID STATE LIGHTING

(76) Inventor: Sung-Sik Chang, Gangwon-do (KR)

(21) Appl. No.: 13/058,068

(22) PCT Filed: Aug. 6, 2009
(86) PCT No.: PCT/KR2009/004405

§ 371 Date: Feb. 8, 2011

(30) Foreign Application Priority Data
Aug. 8, 2008 (KR) 10-2008-0078026

(51) Int. Cl. H01L 33/50; C09K 11/77

(52) U.S. Cl. 257/98; 252/301.4 R; 252/301.6 R; 257/E33.067

(57) ABSTRACT

There are described a red phosphor for use in solid state lighting and a method for preparing the same, which can be excited efficiently with near UV light, blue light and green light. The red phosphor for use in solid state lighting includes a Zn and Ti oxide as a main element and a rare earth element as an additive element. The rare earth element includes a single element or one or more combination thereof selected from a group consisting of Eu, Er, Dy, Sm, Tb, Ce, Gd, Nd, Dy, Ho and the mixture thereof. The Zn and Ti oxide may be one selected from a group consisting of TiZn₂O₄. The red phosphor of the present invention can be prepared by employing a solid state sintering method at an ambient air at atmospheric pressure and in a range of 1,000˜1,500 and thus is simple in preparing process to save cost.

### TECHNICAL FIELD

The present invention relates to a red phosphor and a method for forming the same, and more particularly, to a red phosphor for use in a solid state lighting device and a method for forming the same.

### BACKGROUND ART

Generally, a white light LED has been recognized as a new light source, which is capable of replacing general lighting devices used for a fluorescent lamp at home, and as a LED backlight because the life span of the white light LED is very long. It could be more miniaturized and further driven by a low power source, as compared to an incandescent lamp such as a 60 W economical type-lamp.

In a method for manufacturing the white light LED, it has been proposed to use light emitting diodes in three colors (Red, Green and Blue); however, it has problems in that the manufacturing cost is high, and the product size thereof becomes larger due to the complicate driving circuit. Meanwhile, the white light LED fabricated by combining a blue LED, an InGaN semiconductor having 460 nm wavelength, with an YAG:Ce phosphor has been realized up to now. The blue light emitted from a blue LED excites the YAG:Ce phosphor to generate fluorescence of yellow-green and then blue and yellow-green are combined to emit white light. However, the emitted white light (generated by combining blue LED with YAG:Ce phosphor) has a narrow region of visible light spectrum (lack of red component) and thus a color rendering index is low. As a result, the color can not be expressed properly.

In order to solve the aforementioned problems of the white light LED, various studies on developing the white light LED emitting white light almost similar to natural color has been carried out by using Ultra Violet (“UV”) LED as an exciting light source and combining all of red, green and blue phosphors. Red luminescent material is to be developed essentially in order to fabricate this type of white light LED, which has excellent luminance at a light source of 400 nm wavelength with best device efficiency. That is, while the green and blue phosphors have satisfactory luminance efficiencies, the red luminescent material having excellent luminance efficiency with respect to an UV excitation source has to be developed urgently because the red phosphor has very low luminance efficiency.

Additionally, the luminescent material having good luminance efficiency with respect to near UV excitation source is considered to be very important in developing an active luminescent LCD. The active luminescent LCD is configured in such a manner that the light emitted from a rear surface thereof penetrates into a liquid crystal layer through a polarizer, which allows backlight to pass through or to be shielded by its alignment properly, to form a predetermined displaying type. Subsequently, the backlight passed through the liquid crystal layer excites a corresponding phosphor, thereby displaying images through a front glass. Even though this active luminescent LCD element is simple in structure and can be fabricated easily, as compared to an existing color liquid crystal display device however, emission brightness of the red phosphor among the used phosphors is low so that it is considered not to be practical.

In particular, the active luminescent LCD device has to utilize near UV (light), as a rear surface light source, having a predetermined wavelength equal to or more than 390 nm for protecting a liquid crystal and an UV LED, as a rear surface light source, may be a best one to satisfy this requirement. As a result, it is very important to develop a red luminescent material having good luminance efficiency with respect to near UV in an active luminescent LCD device as well as red and white LED's.

A conventional white light LED has been used by combining a blue LED with an YAG:Ce phosphor. Since a red color portion thereof is deficient, the emission light displays a bluish white color. Furthermore, there arise problems that the red phosphor has low luminescent efficiency, being deteriorated depending on time elapsed and temperature, and it is also impossible to excite it from visible light.

In order to solve the aforementioned problems, CaAlSiN₃ as the red phosphor has been developed. This red phosphor (CaAlSiN₃) utilizes a blue LED light source as an excitation light source, which is stable in a range from room temperature to 100° C. Meanwhile, this red phosphor is made by mixing aluminum nitride, calcium nitride and europium nitride in a globe box shielded from air and moisture and then placing the mixture at about 10 atm and at about 1,800° C. in a nitrogen atmosphere to prepare an Eu solid solution. Here, the preparing method of red phosphor containing CaAlSiN₃ is complicate and raw materials thereof are expensive. Furthermore, the excitation efficiency of the red phosphor with respect to near UV is low.

Meanwhile, researches on the red phosphor have been also conducted in the field of FED (field emission display). In a FED system, the phosphor should be excited by high energy electron beam obtained with high acceleration voltage higher than 1 kV. Therefore, the red phosphor is not appropriate to a solid state lighting system such as an LED which operates at a low voltage (e.g., lower than 10 V).

While the high acceleration voltage higher than 1 kV is required and the property of the red phosphor thereof should be maintained even under high vacuum environment in the FED system, the red phosphor for the solid state lighting system (e.g., LED) should be fully excited by the low power lighting source at a low voltage (e.g., lower than 10 V). Accordingly, there has been wide needs or concerns in the red phosphor that is compatible to a solid state lighting system operating at a low driving voltage.

### DISCLOSURE OF INVENTION

### Technical Problem

Accordingly, an object of the present invention is to provide a red phosphor for use in solid state lighting, which can be prepared in ambient air at atmospheric pressure and can be excited with any one of a near UV, a blue light and a green light, and a method of preparing the same.

It is another object of the present invention to provide a solid state lighting device capable of accomplishing white light emission by employing a red phosphor therein, wherein the red phosphor can be formed in ambient air at atmospheric pressure.

### Solution to Problem

According to one aspect of the present invention, there is provided a red phosphor for use in solid state lighting including a Zn and Ti oxide and a rare earth element.

According to another aspect of the present invention, there is provided a red phosphor which is excited with incident light source from a LED device thereon and consequently emits light, the red phosphor comprising a Zn and Ti oxide as a main element, and a rare earth element, wherein the red phosphor is excited with incident light source thereon and, consequently emits red light.

According to further another aspect of the present invention, there is provided a solid state lighting device including a light emitting diode; and a red phosphor which is excited by light irradiated thereon from the diode and, consequently emits red light, wherein the red phosphor has a Ti and Zn oxide as a main element and a rare earth element as an additive element. The rare earth element may be selected from a group consisting of Eu, Er, Dy, Sm, Tb, Ce, Gd, Nd, Dy, and Ho and a mixture thereof. Eu can be representatively used as the rare earth element.

According to still another aspect of the present invention, there is provided a method for manufacturing a red phosphor comprising the steps of mixing a Zn oxide or a Zn sulfide, a Ti oxide, and a rare earth element oxide and then forming a mixture, and forming a TiZn₂O₄:K (K: rare earth element) red phosphor by thermal treating the mixture in a range of 1,000 to 1,500° C.

### Advantageous Effects of Invention

In a conventional red phosphor, there arise problems that since it is prepared in a nitrogen atmosphere, production utilities are complex; and cost thereof is expensive; and further the red phosphor can not be excited efficiently with UV. However, a red phosphor for use in solid state lighting in accordance with the present invention can be prepared in ambient air at atmospheric pressure with low cost. The red phosphor for use in solid state lighting in accordance with the present invention may include a Ti and Zn oxide as a main element and a rare earth element as an additive element and further can be excited with any one of near UV, blue light and green light. The red phosphor for use in solid state lighting in accordance with the present invention has an advantage for improving color rendering index of a white LED and further has an excellent thermal stability.

### BRIEF DESCRIPTION OF DRAWINGS

The accompanying drawings, which are included to aid in understanding the invention and are incorporated into and constitute a part of this application, illustrate embodiment(s) of the invention and together with the description serve to explain the principles of the invention. In the drawings:

FIG. 1 is a view showing XRD diffraction patterns of TiZn₂O₄:Eu red phosphors which are formed by mixing TiO₂, ZnO and Eu₂O₃ in a predetermined mixing ratio and then heat treating the mixture in accordance with a first embodiment of the present invention;

FIG. 2 is a view showing luminance intensities of the TiZn₂O₄:Eu red phosphors, which are prepared with a variation of an amount (mixing mole ratio) of Eu₂O₃, when the TiZn₂O₄:Eu red phosphors are excited with near UV light of 395 nm and blue light of 465 nm in accordance with the first embodiment of the present invention;

FIG. 3 is a view showing luminance intensities of the TiZn₂O₄:Eu red phosphors excited with near UV light of 395 nm when the TiZn₂O₄:Eu red phosphors are prepared with a variation of an amount (mixing mole ratio) of Eu₂O₃ in accordance with a second embodiment of the present invention;

FIG. 4 a view showing luminance intensities of the TiZn₂O₄:Eu red phosphors excited with blue light of 465 nm when the TiZn₂O₄:Eu red phosphors are prepared with a variation of an amount (mixing mole ratio) of Eu₂O₃ in accordance with the second embodiment of the present invention;

FIG. 5 a view showing luminance intensities of the TiZn₂O₄:Eu red phosphors, which are prepared by mixing TiO₂, ZnO and Eu₂O₃ in a mole ratio of 1.0:1.0:0.08 depending on heat treatment temperature

FIG. 6 is a view showing luminance intensities of the TiZn₂O₄:Eu red phosphors, which are prepared with a variation of an amount (mixing mole ratio) of Eu₂O₃, when the TiZn₂O₄:Eu red phosphors are excited with near UV light of 395 nm and blue light of 465 nm in accordance with a third embodiment of the present invention;

FIG. 7 a view showing excitation spectra of the TiZn₂O₄:Eu red phosphor, a conventional Y₂O₂S:Eu red phosphor and an YAG:Ce red phosphor when the TiZn₂O₄:Eu red phosphor is prepared by mixing TiO₂, ZnO, Eu₂O₃ in a mole ratio of 1.0:1.0:0.08 in accordance with a preferred embodiment of the present invention;

FIG. 8 a view showing luminance intensities of the TiZn₂O₄:Eu red phosphor, the conventional Y₂O₂S:Eu red phosphor and the YAG:Ce red phosphor, which are excited with blue light of near UV light of 395 nm, when the TiZn₂O₄:Eu red phosphor is prepared in an optimal mixing mole fraction of Eu₂O₃ in accordance with a preferred embodiment of the present invention; and

FIG. 9 a view showing luminance intensities of the TiZn₂O₄:Eu red phosphor, the conventional Y₂O₂S:Eu red phosphor and the YAG:Ce red phosphor, which are excited with blue light of 465 nm, when the TiZn₂O₄:Eu red phosphor is prepared in an optimal mixing mole fraction of Eu₂O₃ in accordance with a preferred embodiment of the present invention.

### BEST MODE FOR CARRYING OUT THE INVENTION

In accordance with a preferred embodiment of the present invention, a red phosphor including a Ti and Zn oxide (hereinafter, may be also referred to as “Ti—Zn oxide”) may be prepared by mixing a Ti oxide, a Zn oxide and an Eu oxide in an optimal mole fraction and heating the mixture in a range of 1,000 to 1,500° C. in ambient air atmospheric pressure in order to overcome the aforementioned problems in the prior art. Here, a Ti and Zn oxide refers to compounds containing Ti, Zn and oxygen (O) as chemical elements such as TiZn₂O₄, which are represented as TiₓZn_{y}O_{z}.

Hereinafter, the red phosphors according to the preferred embodiments of the present invention can be used as a material to make white light in white light LEDs. However, it should be noted that the red phosphors in accordance with the preferred embodiments of the present invention are not limited to the white LEDs. The red phosphors can be applied to various electronic devices.

Additionally, while there is described that Eu is used as a representative rare earth element in the embodiments of the present invention, a person who has an ordinary skill in the art to which the invention pertains may choose other rare earth elements instead of Eu. That is, a rare earth element may be selected from a group consisting of Eu, Er, Dy, Sm, Tb, Ce, Gd, Nd, Dy, and Ho as a single element or one or more combination thereof.

### MODE FOR THE INVENTION

### First Embodiment

### Preparing Red Phosphor of TiZn₂O₄:Eu

Slurry is formed by mixing a proper amount of raw materials of TiO₂, ZnO and Eu₂O₃ with an alcohol solvent using a mortar until alcohol is vaporized. Alternatively, the raw materials may be weighed in a stoichiometric ratio and mixed with an alcohol solvent using an yttria stabilized zirconia ball. Thereafter, the raw materials mixed well with the alcohol solvent are ball milled for 24 hours, dried in an oven of 95° C. and then mixed in a mortar to be formed as a pellet or powder. Subsequently, the raw materials are heated in a range of 1,000 to 1,500° C. (more preferably, 1,200 to 1,400° C. in ambient air at atmospheric pressure. At this time, the mixing of Eu₂O₃ is carried out in a mole ratio of 0.05 to 0.10.

Table 1 shows a mole ratio of TiO₂, ZnO, TiO₂ and Eu₂O₃ and a mixing fraction of Eu₂O₃ at such a mixing ratio in accordance with a first embodiment of the present invention. In accordance with the first embodiment of the present invention, the mixing mole ratio of TiO₂ and ZnO is varied and the mixing mole fraction of Eu₂O₃ to a total of ZnO, TiO₂, Eu₂O₃ ranges from 0.0119 to 0.0476.

TABLE 1
Mixing mole ratio of raw materials when preparing
TiZn₂O₄:Eu red phosphor

| | | | | Fraction of |
|---|---|---|---|---|
| Embodiments(experimental | | | | Eu₂O₃ to a |
| Conditions) | TiO₂ | ZnO | Eu₂O₃ | total of raw material |
| Embodiment 1 | 1.0 | 1.0 | 0.05 | 0.0244 |
| Embodiment 2 | 1.0 | 1.0 | 0.10 | 0.0476 |
| Embodiment 3 | 1.0 | 2.0 | 0.05 | 0.0164 |
| Embodiment 4 | 1.0 | 2.0 | 0.10 | 0.0323 |
| Embodiment 5 | 2.0 | 1.0 | 0.05 | 0.0164 |
| Embodiment 6 | 2.0 | 1.0 | 0.10 | 0.0323 |
| Embodiment 7 | 3.0 | 1.0 | 0.05 | 0.0123 |
| Embodiment 8 | 3.0 | 1.0 | 0.10 | 0.0244 |
| Embodiment 9 | 3.0 | 2.0 | 0.06 | 0.0119 |
| Embodiment 10 | 3.0 | 2.0 | 0.10 | 0.0196 |

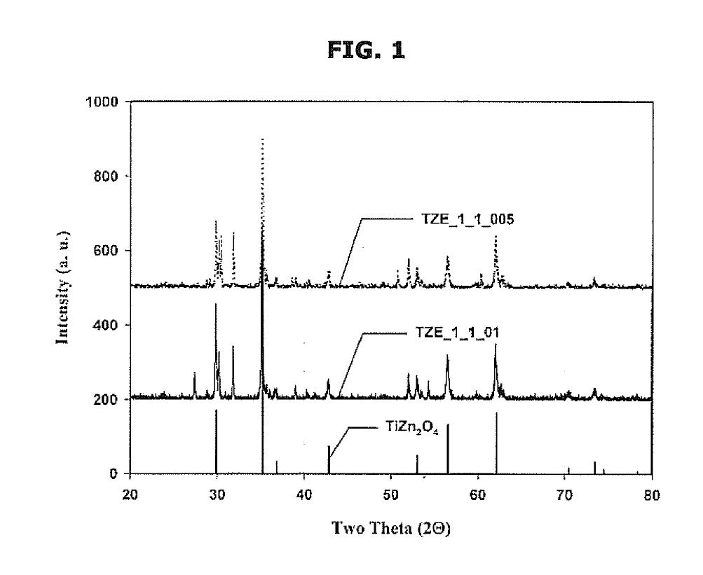

FIG. 1 is a view showing XRD diffraction patterns of a TiZn₂O₄:Eu (Ti and Zn oxide is TiZn₂O₄) (represented as “TZE” in FIG. 1) red phosphors formed by mixing TiO₂, ZnO and Eu₂O₃ in a predetermined mixing ratio and then heat treating the mixture in accordance with the first embodiment of the present invention. Referring to FIG. 1, it is understood that a single phase of TiZn₂O₄ is substantially formed under experimental conditions (embodiments 1 and 2 in table 1) in accordance with the first embodiment of the present invention. In FIG. 1, 1_{—}1_{—}005 next to TZE indicates a mixing mole fraction of TiO₂, ZnO and Eu₂O₃ (1.0:1.0:0.05).

Observation of Luminance Intensity

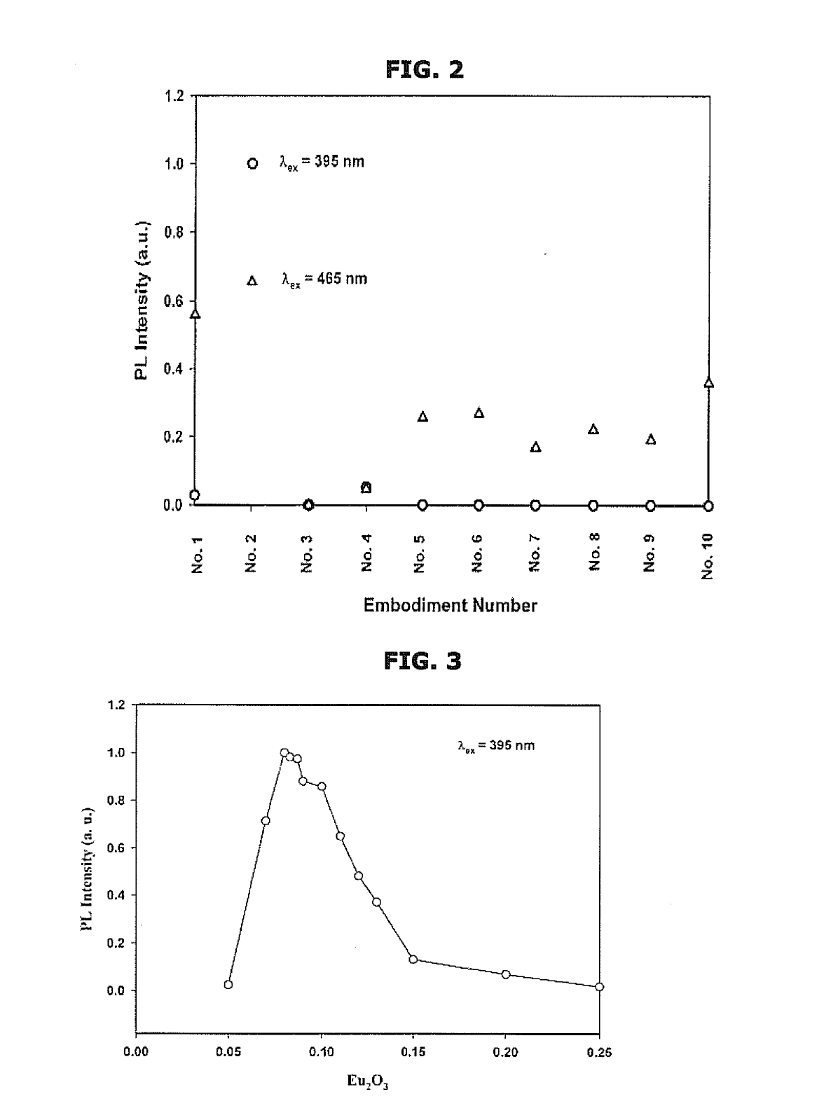

FIG. 2 is a view illustrating luminance intensities of the TiZn₂O₄:Eu red phosphors, which are prepared with a variation of an amount (mixing mole ratio) of Eu₂O₃ to each of experimental conditions (embodiments 1 to 10) when the TiZn₂O₄:Euᵣ red phosphors are excited with near UV light of 395 nm and blue light of 465 nm in accordance with the first embodiment of the present invention.

Observation of the Optimal Mixing Mole Fraction of Eu₂O₃

Referring to Table 1 and FIG. 2, it is observed that the optimal mixing mole ratio of TiO₂ and ZnO allowing luminance intensity of the TiZn₂O₄:Eu red phosphor to be maximized is 1.0:1.0. Hereinafter, in accordance with a second embodiment of the present invention, the mixing mole ratio of Eu₂O₃ is varied under the condition that the mixing mole ratio of TiO₂ and ZnO is fixed to 1.0:1.0.

### Second Embodiment

### Preparing Red Phosphor of TiZn₂O₄:Eu

Slurry is formed by mixing a proper amount of raw materials of TiO₂, ZnO and Eu₂O₃ with an alcohol solvent using a mortar until alcohol is vaporized. Alternatively, the raw materials may be weighed in a stoichiometric ratio and mixed with an alcohol solvent using an yttria-stabilized zirconia ball. Thereafter, the raw materials mixed well with the alcohol solvent is ball milled for 24 hours, dried in an oven of 95° C. and then mixed in a mortar to be formed as a pellet or powder. Subsequently, the raw materials are heated in a range of 1,000 to 1,500° C. (more preferably, 1,200 to 1,400° C. in ambient air at atmospheric pressure. At this time, the mixing of Eu₂O₃ is carried out in a mole ratio of 0.05 to 0.25.

Table 2 shows a mole ratio of TiO₂, ZnO, TiO₂ and Eu₂O₃ and a mixing fraction of Eu₂O₃ such a mixing ratio in accordance with a second embodiment of the present invention. In accordance with the second embodiment of the present invention, the mixing mole fraction of Eu₂O₃ to a total Zn₂O₃, TiO₂, Eu₂O₃ ranges from 0.0244 to 0.1111 under the condition that mixing mole ratio of TiO₂ and ZnO is fixed to 1.0:1.0.

TABLE 2
Mixing mole ratio of raw materials when preparing
TiZn₂O₄:Eu red phosphor

| | | | | Fraction of |
|---|---|---|---|---|
| Embodiments(experimental | | | | Eu₂O₃ to a |
| Conditions) | TiO₂ | ZnO | Eu₂O₃ | total of raw material |
| Embodiment 1 | 1.0 | 1.0 | 0.05 | 0.0244 |
| Embodiment 2 | 1.0 | 1.0 | 0.07 | 0.0338 |
| Embodiment 3 | 1.0 | 1.0 | 0.08 | 0.0385 |
| Embodiment 4 | 1.0 | 1.0 | 0.083 | 0.0398 |
| Embodiment 5 | 1.0 | 1.0 | 0.087 | 0.0417 |
| Embodiment 6 | 1.0 | 1.0 | 0.09 | 0.0431 |
| Embodiment 7 | 1.0 | 1.0 | 0.10 | 0.0476 |
| Embodiment 8 | 1.0 | 1.0 | 0.11 | 0.0521 |
| Embodiment 9 | 1.0 | 1.0 | 0.12 | 0.0566 |
| Embodiment 10 | 1.0 | 1.0 | 0.13 | 0.0610 |
| Embodiment 11 | 1.0 | 1.0 | 0.15 | 0.0698 |
| Embodiment 12 | 1.0 | 1.0 | 0.20 | 0.0909 |
| Embodiment 13 | 1.0 | 1.0 | 0.25 | 0.1111 |

Observation of Luminance Intensity Spectrum

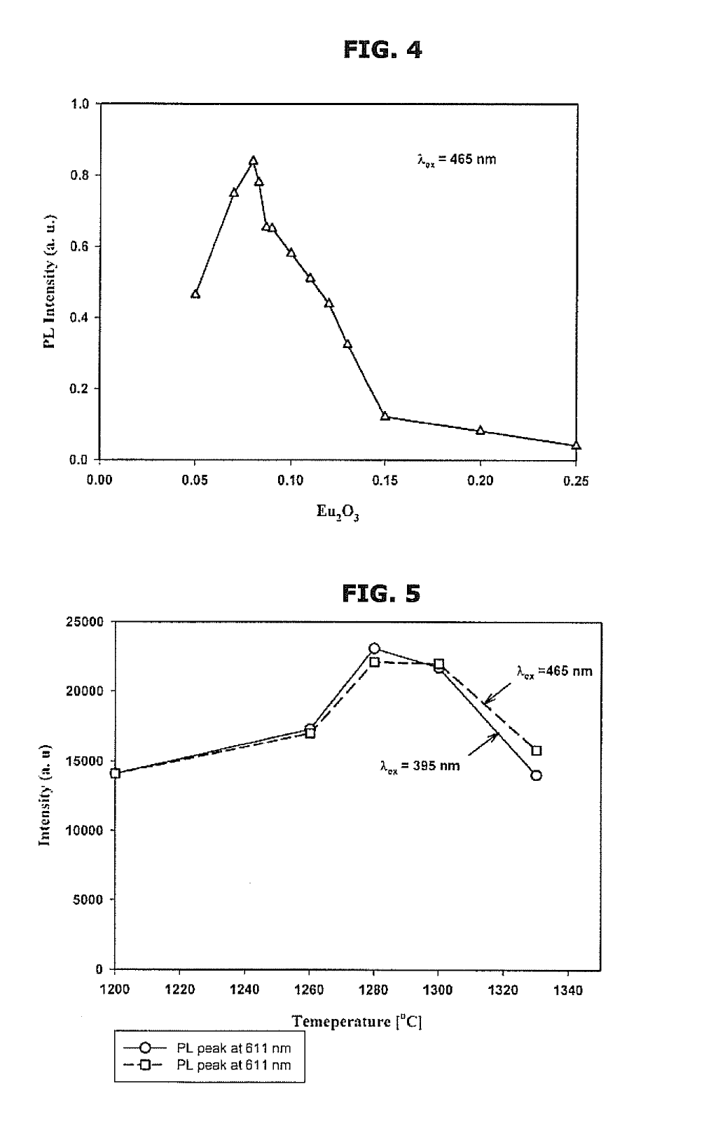

FIG. 3 is a view showing luminance intensities of the TiZn₂O₄:Eu red phosphors excited with near UV light of 395 nm when the TiZn₂O₄:Eu red phosphors are prepared with a variation of an amount (mixing mole ratio) of Eu₂O₃ in accordance with the second embodiment of the present invention. FIG. 4 a view showing luminance intensities of the TiZn₂O₄:Eu red phosphors excited with blue light of 465 nm when the TiZn₂O₄:Eu red phosphors are prepared with a variation of an amount (mixing mole ratio) of Eu₂O₃ in accordance with the second embodiment of the present invention.

As shown in FIGS. 3 and 4, the optimal mixing ratio of Eu₂O₃ is about 0.08 (a corresponding fraction of Eu₂O₃ to a total of raw material is 0.0385) and further the luminance intensity thereof is decreased at a concentration of no less than about 0.08 due to an excessive concentration and at no more than about 0.08 due to a deficient concentration of an activator, respectively.

Observation of the Optimal Mixing Mole Fraction of Eu₂O₃

Referring to Table 2, FIGS. 3 and 4, it is observed that maximum luminance intensity peak of the TiZn₂O₄:Eu red phosphor excited with near UV light of 395 nm and blue LED light of 465 nm is achieved at embodiment 3. Accordingly, it is understood that the optimal mixing mole fraction of Eu₂O₃ to a total of raw material is 0.0385.

FIG. 5 is a view showing luminance intensities of the TiZn₂O₄:Eu red phosphors, which are prepared by mixing TiO₂, ZnO and Eu₂O₃ in a mole ratio of 1.0:1.0:0.08 depending on heat treatment temperature in accordance with the second embodiment of the present invention. Referring to FIG. 5, the maximum luminance intensity peak of the TiZn₂O₄:Eu red phosphor excited with near UV light of 395 nm and blue LED light of 465 nm is achieved with a heat treatment in a range of 1280 to 1300° C.

### Third Embodiment

### Preparing Red Phosphor of TiZn₂O₄:Eu

Slurry is formed by mixing a proper amount of raw materials of TiO₂, ZnO and Eu₂O₃ with an alcohol solvent in a mortar until alcohol is vaporized. Alternatively, the raw materials may be weighed at stoichiometric ratio and mixed with the alcohol solvent using an yttria-stabilized zirconia ball. Thereafter, the raw materials mixed well with the alcohol solvent is ball milled for 24 hours, dried in an oven of 95° C. and then mixed in a mortar to be formed as a pellet or powder. Subsequently, the raw materials are heated in a range of 1,000 to 1,500° C. (more preferably, 1,200 to 1,400° C. in ambient air at atmospheric pressure. At this time, the mixing of Eu₂O₃ is carried out in a mole ratio of 0.05 to 0.1.

Table 3 shows a mole ratio of TiO₂, ZnO, TiO₂ and Eu₂O₃ and a mixing fraction of Eu₂O₃ at such a mixing ratio in accordance with a third embodiment of the present invention. In accordance with the third embodiment of the present invention, the mixing mole fraction of Eu₂O₃ to a total ZnO, TiO₂, Eu₂O₃ is 0.0244 or 0.0476 under the condition that mixing mole ratio of TiO₂ and ZnO (or ZnS) is fixed to 1.0:1.0.

TABLE 3
Mixing mole ratio of raw materials when preparing
TiZn₂O₄:Eu red phosphor

| Embodiments | | | | | |
|---|---|---|---|---|---|
| (experimental | | | | | Fraction of Eu₂O₃ to a |
| Conditions) | TiO₂ | ZnO | ZnS | Eu₂O₃ | total of raw material |
| Embodiment 1 | 1.0 | 1.0 | — | 0.05 | 0.0244 |
| Embodiment 2 | 1.0 | 1.0 | — | 0.10 | 0.0476 |
| Embodiment 3 | 1.0 | — | 1.0 | 0.05 | 0.0244 |
| Embodiment 4 | 1.0 | — | 1.0 | 0.10 | 0.0476 |

Observation of Luminance Spectrum

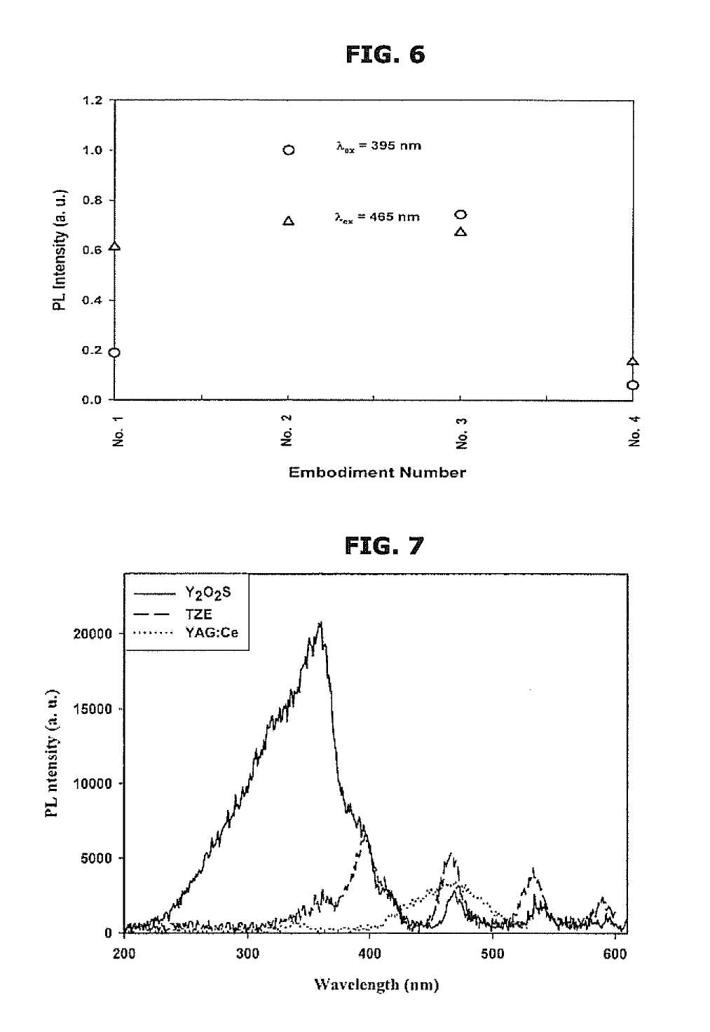

FIG. 6 is a view showing luminance intensities of the TiZn₂O₄:Eu red phosphors, which are is prepared with a variation of an amount (mixing mole ratio) of Eu₂O₃ when the TiZn₂O₄:Eu red phosphors are excited with near UV light of 395 nm and blue light of 465 nm in accordance with a third embodiment of the present invention.

Referring to Table 3 and FIG. 6, it is understood that ZnS can be used, instead of ZnO, for a proper red phosphor.

Observation of Excitation Spectrum

FIG. 7 is a view showing excitation spectra of the TiZn₂O₄:Eu red phosphor, a conventional Y₂O₂S:Eu red phosphor and an YAG:Ce red phosphor when the TiZn₂O₄:Eu red phosphor is prepared by mixing TiO₂, ZnO, Eu₂O₃ in a mole ratio of 1.0:1.0:0.08 (i.e., optimal mixing mole ratio) in accordance with a preferred embodiment of the present invention.

Referring to FIG. 7, it is observed that the TiZn₂O₄:Eu red phosphor, which is prepared at the optimal mixing mole ratio in accordance with the preferred embodiments of the present invention, has a similar excitation peak value on near UV of 395 nm and has a greater excitation peak value on blue LED light of 465 nm, as compared to the conventional Y₂O₂S:Eu red phosphor. Further, it is observed that the TiZn₂O₄:Eu red phosphor, which is prepared at the optimal mixing mole ratio in accordance with the preferred embodiments of the present invention, has a greater excitation peak value on near UV of 395 nm and blue light of 465 nm, as compared to the conventional YAG:Ce red phosphor.

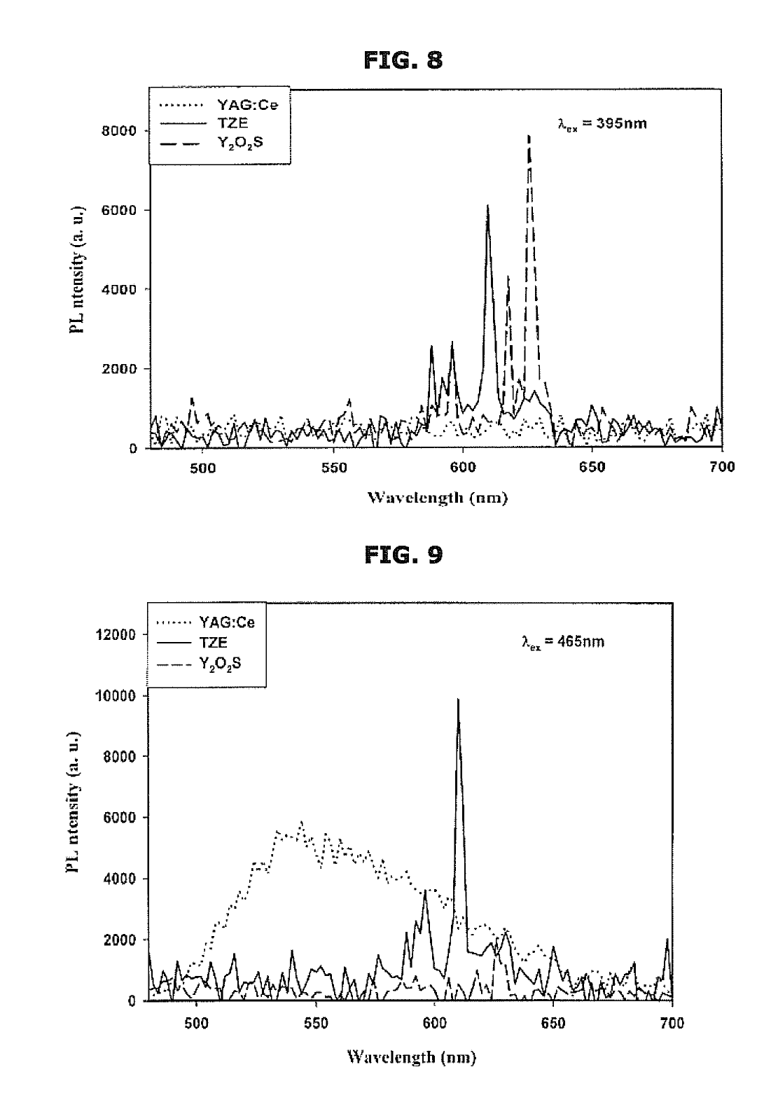

Hereinafter, based on the results of the first to third embodiments as aforementioned, the characteristics of the TiZn₂O₄:Eu red phosphor will more described referring to FIGS. 8 and 9. FIG. 8 is a view showing luminance intensities of the TiZn₂O₄:Eu red phosphor, the conventional Y₂O₂S:Eu red phosphor and the YAG:Ce red phosphor, which are excited with near UV light of 395 nm, when the TiZn₂O₄:Eu red phosphor (represented as TZE) is prepared in an optimal mixing mole fraction of Eu₂O₃ in accordance with a preferred embodiment of the present invention. FIG. 9 is a view showing luminance intensities of the TiZn₂O₄:Eu red phosphor, a conventional Y₂O₂S:Eu red phosphor and the YAG:Ce red phosphor, which are excited with blue light of blue light of 465 nm, when the TiZn₂O₄:Eu red phosphor (represented as TZE) is prepared in an optimal mixing mole fraction of Eu₂O₃ in accordance with a preferred embodiment of the present invention.

Referring to FIGS. 8 and 9, while the luminescence intensity of TiZn₂O₄:Eu red phosphor is less than that of the prior art Y₂O₂S:Eu red phosphor when they are excited with near UV light of 395 nm, the luminescence intensity of TiZn₂O₄:Eu red phosphor is far greater than that of the Y₂O₂S:Eu and YAG:Ce when they are excited with blue light of 465 nm. Referring to FIGS. 8 and 9, the TiZn₂O₄:Eu red phosphor in accordance with the embodiments of the present invention can be excited efficiently with any one of near UV light, blue light and green light. Here, it should be noted that the above-mentioned red phosphors can be used for one or more of near UV, blue light and green light sources.

As aforementioned, various embodiments of preparing a red phosphor for use in a solid state lighting device including a Ti oxide and a Zn oxide as a main element and a rare earth element (such as Eu) as an additive element have been described in detail.

Meanwhile, in accordance with another aspect of the present invention, the red phosphor for the solid state lighting device, which includes the Ti and Zn oxide as a main element, can be also prepared from raw material such as chloride, nitride, sulfide and hydroxide of Ti and/or Zn. In this case, chloride, nitride, sulfide and hydroxide of Ti and/or Zn may be mixed with each other together with a proper raw material of a rare earth element and then heat treated.

In the course of such a process, each of chloride, nitride, sulfide and hydroxide of Ti and/or Zn is dissociated through thermal heat treatment and Ti and Zn are combined each other with oxygen (O) to thereby form a Ti—Zn oxide red phosphor including a Ti and Zn oxide as a main element and a rare earth element (such as Eu) as a subsidiary element. More detailed description thereof is omitted since the person with ordinary skill in the art can design variously the process referring to the first to third embodiments of the present invention.

While this invention has been described in conjunction with the specific embodiments outlined above, it is evident that many alternatives, modifications and variations will be apparent to those skilled in the art. Accordingly, the preferred embodiments of the invention as set forth above are intended to be illustrative, not limiting. Various changes may be made without departing from the spirit and scope of the invention as defined in the following claims.

1. A red phosphor for use in a solid state lighting device comprising:
a Ti and Zn oxide as a main element; and
a rare earth element.

2. The red phosphor according to claim 1, wherein the rare earth element is selected from a group consisting of Eu, Er, Dy, Sm, Tb, Ce, Gd, Nd, Dy, and Ho and a mixture thereof.

3. The red phosphor according to claim 2, wherein the Ti and Zn oxide is TiZn₂O₄.

4. The red phosphor according to claim 1, wherein the red phosphor is excited with an exciting source and then emits red light, wherein the exciting source is any one of near UV light, blue light and green light.

5. A red phosphor which is excited with incident light source from a LED device thereon and consequently emits light, the red phosphor comprising:
a Zn and Ti oxide as a main element; and
a rare earth element.

6. The red phosphor according to claim 5, wherein the rare earth element is selected from a group consisting of Eu, Er, Dy, Sm, Tb, Ce, Gd, Nd, Dy, and Ho and a mixture thereof.

7. The red phosphor for use in solid state lighting according to claim 6, wherein the Ti and Zn oxide is TiZn₂O₄.

8. A solid state lighting device comprising:
a light emitting diode; and
a red phosphor which is excited by light irradiated thereon from the diode and, consequently emits red light, wherein the red phosphor has a Ti and Zn oxide as a main element and a rare earth element as an additive element.

9. The solid state lighting device according to claim 8, wherein the rare earth element is selected from a group consisting of Eu, Er, Dy, Sm, Tb, Ce, Gd, Nd, Dy, and Ho and a mixture thereof.

10. The solid state lighting device according to claim 8, wherein the red phosphor is excited with any one of near UV light, blue light and green light.

11. The solid state lighting device according to claim 8, wherein the light emitting diode is a white light LED.

12. The solid state lighting device according to claim 8, wherein the Ti and Zn oxide is TiZn₂O₄.

13. A method for manufacturing a red phosphor comprising the steps of:
mixing a Zn oxide or a Zn sulfide, a Ti oxide, and a rare earth element oxide and then forming a mixture; and
forming a TiZn₂O₄:K (K: rare earth element) red phosphor by thermal treating the mixture in a range of 1,000 to 1,500° C.

14. The method according to claim 13, wherein the rare earth element is selected from a group consisting of Eu, Er, Dy, Sm, Tb, Ce, Gd, Nd, Dy, and Ho and a mixture thereof.

15. The method according to claim 14, wherein the Ti oxide is TiO₂, Zn oxide is ZnO, and Eu oxide is Eu₂O₃.

16. The method according to claim 15, wherein a mixing mole fraction of Eu₂O₃ to a total of TiO₂, ZnO and Eu₂O₃ is 0.0119 to 0.1111.

17. The method according to claim 14, wherein the step of forming the TiZn₂O₄:K is carried out in ambient air at atmospheric pressure.
